(19) United States
(12) Patent Application Publication
(10) Pub. No.: US 2018/0212107 A1
(43) Pub. Date: Jul. 26, 2018

(54) Optoelectronic Semiconductor Chip

(71) Applicant: OSRAM Opto Semiconductors GmbH, Regensburg (DE)

(72) Inventors: Philipp Kreuter, Regensburg (DE); Markus Bröll, Regensburg (DE); Jens Müller, Regensburg (DE)

(73) Assignees: OSRAM Opto Semiconductors GmbH, Regensburg (DE); OSRAM Opto Semiconductors GmbH, Regensburg (DE)

(21) Appl. No.: 15/742,871

(22) PCT Filed: Jul. 7, 2016
(86) PCT No.: PCT/EP2016/066060

§ 371 Date: Jan. 8, 2018

(30) Foreign Application Priority Data
Jul. 8, 2015 (DE) 102015111046.6

(51) Int. Cl. H01L 33/38; H01L 33/62; H01L 33/20; H01L 33/00

(52) U.S. Cl. CPC H01L 33/382; H01L 33/0062; H01L 33/20; H01L 33/62

(57) ABSTRACT

An optoelectronic semiconductor chip is disclosed. In an embodiment, the chip includes a semiconductor layer sequence with a first side, a second side and an active zone and at least one via electrically contacting the first side with the second side through the active zone, wherein the via has a base region including a cylinder, a truncated cone or a truncated pyramid, wherein the via is surrounded in a lateral direction by an electric insulation layer, wherein the via has a contact region including a truncated cone, a truncated pyramid, or a spherical or aspherical body, wherein the contract region directly follows the base region, wherein the contact region is in direct contact with the second side, wherein a first flank angle of the base region is different from a second flank angle of the contact region, and wherein the first and second flank angles are related to the lateral direction.

An optoelectronic semiconductor chip is specified.

An object to be achieved consists in specifying an optoelectronic semiconductor chip, which can be electrically contacted efficiently and which has a high radiation outcoupling efficiency.

This object is achieved among other things by an optoelectronic semiconductor chip with the features of the independent claim. Preferred developments are the object of the dependent claims.

According to at least one embodiment, the optoelectronic semiconductor chip is configured to generate radiation. The semiconductor chip is in particular a light-emitting diode chip, also termed LED chip. For example, visible light, ultraviolet radiation or infrared radiation is emitted by the optoelectronic semiconductor chip during operation.

According to at least one embodiment, the semiconductor chip comprises a semiconductor layer sequence. The semiconductor layer sequence is grown epitaxially, for example. The semiconductor layer sequence is preferably based on a III-V-compound semiconductor material. The semiconductor material is for example a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or also AlInGaAsP, wherein 0≤n≤1, 0≤m≤1 and n+m≤1 respectively. Here the semiconductor layer sequence can have dopants as well as additional components. However, for the sake of simplicity only the substantial components of the crystal lattice of the semiconductor sequence, thus Al, As, Ga, In, N or P, are specified, even if these can be partially replaced and/or supplemented by small quantities of other substances.

According to at least one embodiment, the semiconductor layer sequence comprises a first side, a second side and an active zone lying in between. The active zone is configured to generate radiation. The first side and the second side can each comprise one or more partial layers of the semiconductor layer sequence. The first side and the second side exhibit different conductivity types from one another. For example, the first side is an overall p-doped region of the semiconductor layer sequence and the second side an overall n-doped region or vice-versa. The first side, the active zone and the second side follow one another, preferably directly follow one another, along a growth direction of the semiconductor layer sequence.

According to at least one embodiment, the semiconductor chip comprises one or, preferably, several vias. The at least one via is configured to energize the second side. From the first side the via runs through the active zone and extends into the second side, so that the second side is electrically contacted by means of the via. The fact that the via runs through the active zone can mean that, seen in plan view, the via is surrounded all around by a closed path of the active zone. In this case preferably no evacuated or gas-filled gap is located between the via and the active zone.

According to at least one embodiment, the via has a base region. The base region can taper in the direction of the second side.

The base region has the shape in particular of a cylinder, a truncated cone or a truncated pyramid. Here the terms cylinder and truncated cone include the fact that the cone or cylinder, seen in plan view, can also have an ellipse as a basic shape. Due to the manufacture it is possible that the shape of the via may deviate slightly from the ideal shape of a truncated cone or a truncated pyramid.

According to one embodiment, the base region of the via is surrounded all around, preferably directly surrounded, by an electric insulation layer. This means that all around in a lateral direction an electric insulation layer follows the via in the base region towards the outside. No direct electric contact preferably then exists between the base region and the semiconductor layer sequence. The lateral direction is oriented in this case perpendicular to the growth direction of the semiconductor layer sequence.

According to at least one embodiment, the via has a contact region. The contact region directly follows the base region in the direction away from the first side. In particular, the base region and the contact region are constructed in one piece.

According to at least one embodiment, the contact region represents an elevation above the base region, in a direction parallel to the growth direction. Here the contact region preferably has the shape of a truncated cone or a truncated pyramid. Alternatively it is possible that the contact region is formed as a hemisphere or semi-ellipsoid or domed, spherical or even aspherical body. Preferably, however, the contact region has a flat or approximately flat boundary surface to the semiconductor layer sequence in the direction away from the base region.

According to at least one embodiment, the contact region is in direct contact with the second side of the semiconductor layer sequence, in particular only with the second side. It is possible hereby that a current is impressed into the second side via the contact region.

According to at least one embodiment, the base region has a first flank angle and the contact region has a second flank angle. The flank angles are in this case the angles between the lateral direction and the lateral surfaces of the base region and the contact region. The angles are preferably measured here in a plane in which both the lateral direction and the growth direction lie. The first flank angle is particularly preferably different from the second flank angle. In other words, the base region and the contact region then merge into one another through a bend or through a curvature of the shell surfaces.

In at least one embodiment, the optoelectronic semiconductor chip, which is preferably an LED chip, comprises a semiconductor layer sequence. The semiconductor layer sequence has a first side and a second side and an active zone lying in between. The two sides exhibit different conductivity types. The second side is electrically contacted from the first side through the active zone by at least one via. The via contains a base region, which is preferably in the shape of a cylinder, truncated cone or truncated pyramid and which is surrounded all around in a lateral direction, perpendicular to a growth direction of the semiconductor layer sequence, by an electric insulation layer. The via further has a contact region, which is formed spherical or aspherical or, preferably, is likewise in the shape of a truncated cone or truncated pyramid and which directly follows the base region in a direction parallel to the growth direction and is in direct contact with the second side. A first flank angle of the base region is different from a second flank angle of the contact region relative to the lateral direction in each case.

In light-emitting diode chips, lateral wave guiding can take place in an active zone if the active zone has a higher refractive index than surrounding semiconductor material. Wave guiding in the active zone normally results in a reduction of an outcoupling probability and leads to increased optical losses due to reabsorption in the active zone. Furthermore, a diameter of vias that are led through the active zone should be kept small on account of non-radiative recombination centers arising at this boundary surface. However, this leads to a limiting of a via contact surface with the semiconductor layer sequence and thus to a limiting for a reduction of a series resistance contribution through the vias. In such vias the contact surface is typically equivalent to a head surface of the vias. A series resistance contribution of the vias is thus limited by their diameter.

In the case of oblique lateral surfaces of vias, light guided in the active zone can scatter on the vias. Another possibility for preventing or diminishing lateral wave guiding is etched microprisms, which are led very close to the active zone to scatter light.

In the case of the semiconductor chip described here, vias can be used on the one hand to improve a light outcoupling efficiency. By dividing the via into a contact region and a base region the electric properties can be optimized at the same time.

In other words, the contact surfaces of the via are increased with the same lateral size in the optoelectronic semiconductor chip described here. This is achieved by executing the vias as truncated cones with a stepped flank angle. Thus an upper part of the vias, the contact region, is not passivated on the shell surfaces and connects electrically to the semiconductor layer sequence. In the contact region, in which the via is coupled electrically to the semiconductor layer sequence, the second flank angle between a surface line and a cone axis is different from the corresponding angle of the remaining via, thus of the base region.

Here the greatest possible second flank angles, thus as parallel as possible to the growth direction, are preferred for the contact region to achieve a particularly large contact surface. In this case, however, limits may be set on the second flank angle by process parameters. The second flank angle can be optimized here independently of the first flank angle, so that the optical properties are preferably not, or not significantly, impaired by the contact region. Independent optimization of the optical and electric properties is thus possible by the division into the contact region and the base region.

Since the shell surfaces of the vias can be used to scatter the light generated in the active zone, additional microprism etching, which sharply constricts a current flow in a lateral direction through the active zone and has a negative effect on the reliability of the semiconductor chip, can be eliminated.

The vias necessary for the electric connection of the component can be optimized at the same time in respect of their contact resistance as well as being used to optimize the optical properties, in particular the light outcoupling.

According to at least one embodiment, the first flank angle and the second flank angle differ from one another, in particular in amount, by at least 3° or 10° or 15°. Alternatively or in addition, this difference is at most 90° or 35° or 25° or 20°. Here the first flank angle is preferably greater than the second flank angle.

According to at least one embodiment, the first flank angle is at least 40° or 50° and/or is at most 90° or 70° or 60°.

Alternatively or in addition the second flank angle is at least 20° or 25° or 35° and/or at most 120° or 90° or 65° or 55° or 45°.

According to at least one embodiment, the contact region has a height in the direction parallel to the growth direction that is at least 0.05 μm or 0.2 μm or 0.4 μm. Alternatively or in addition this height is at most 4 μm or 2 μm or 1.5 μm.

According to at least one embodiment, the following applies to the height h of the contact region and to a mean diameter dl of the via: 1≤d1/h or 3≤d1/h or 7≤d1/h and/or d1/h≤10 or d1/h≤20 or d1/h≤30. Here d1 is the mean diameter of the via at the boundary between the contact region and the base region along the lateral direction.

According to at least one embodiment, the mean diameter d1 is at least 1 μm or 2 μm or 4 μm. Alternatively or in addition, the mean diameter dl is at most 50 μm or 40 μm or 30 μm.

According to at least one embodiment, the base region has a base height in the direction parallel to the growth direction. The base height is at least 200 nm or 1 μm or 2 μm and/or at most 30 μm or 15 μm or 5 μm. Alternatively or in addition, it is the case that the base height is at least as great as a sum of the thicknesses of the active zone and the first side+100 nm of these thicknesses.

According to at least one embodiment, at least one of the following relationships applies to the base height H and to the height h of the contact region: 0.2≤H/h or 3≤H/h or 6≤H/h and/or H/h≤15 or H/h≤30 or H/h≤40.

According to at least one embodiment, the contact region exhibits one or more of the following materials at a boundary surface to the semiconductor layer sequence or consists there of one or more of these materials: Au, Ag, indium-tin-oxide or ITO for short, ZnO, Ni, Ge, Zn, Rh, Pd, Pt, Ti.

According to at least one embodiment, the base region consists predominantly of one or more of the following materials: Ag, Au, ITO, ZnO, Ni, Ge, Zn, Rh, Pd, Pt, Ti, Sn, W. The term predominantly means that a mass fraction and/or a volume fraction of the corresponding material is at least 50% or 75%.

According to at least one embodiment, the via is a metal via. This means that the via is formed of one or more metals. The metal components of the via then account preferably for at least 90% by mass or 95% by mass or 99% by mass.

According to at least one embodiment, radiation with a dominant wavelength is generated in the active zone. The dominant wavelength here is the wavelength at which a maximum intensity exists, measured in W or W/nm.

According to at least one embodiment, the insulation layer that surrounds the base region of the via has a mean thickness. The mean thickness is determined here in a direction perpendicular to a shell surface of the base region.

According to at least one embodiment, the following relationship applies in respect of the dominant wavelength A and the mean thickness D of the insulation layer: D>λ/4n or D>3λ/8n or D>5λ/8n and/or D<2λ/n or D<3λ/2n or D<3λ/4n. Here n is the refractive index of the insulation layer at the dominant wavelength.

According to at least one embodiment, the insulation layer tapers in the direction of the contact region. In this case a thickness of the insulation layer can decrease continuously in the direction of the contact region. The decrease in thickness can take place linearly or approximately linearly.

According to at least one embodiment, the semiconductor chip has a plurality of vias. Seen in plan view, a surface density of the vias here is preferably at least 20/mm² or 30/mm² or 50/mm². Alternatively or in addition, the density of the vias is at most 500/mm² or 300/ mm² or 150/mm². The vias are preferably arranged in a regular pattern when seen in plan view. For example, the vias are applied in a square or rectangular or hexagonal grid. Corresponding mean distances between adjacent vias result from the surface density of the vias.

According to at least one embodiment, the semiconductor layer sequence is based on the material system AlInAsGaP or AlInGaP. The semiconductor chip is then preferably configured for the emission of yellow, orange or red light or of near-infrared radiation.

According to at least one embodiment, the second side is p-doped and the first side is n-doped. It is possible for the second side to comprise a doping layer as well as a contact layer or to consist of these. In this case the contact layer is doped more highly than the doping layer, for example by at least a factor of 2 or 5 or 10 more highly doped. The doping layer directly borders the active zone, for example, but is preferably spaced from the active zone. Due to the lower dopant concentration it is possible for the doping layer to have a higher crystal quality than the contact layer, due to which a quality of the active zone can also be improved.

According to at least one embodiment, the via extends into the contact layer. In other words, the contact region of the via then ends in the contact layer. In particular, the contact region of the via is located completely in the contact layer. A corresponding division into a doping layer and a contact layer can also be present on the first side.

An optoelectronic semiconductor chip described here is explained in greater detail below with reference to the drawing on the basis of exemplary embodiments. Here the same reference signs indicate identical elements in the individual figures. However, no references to scale are shown; on the contrary, individual elements can be shown exaggeratedly large for a better understanding.

The figures show:

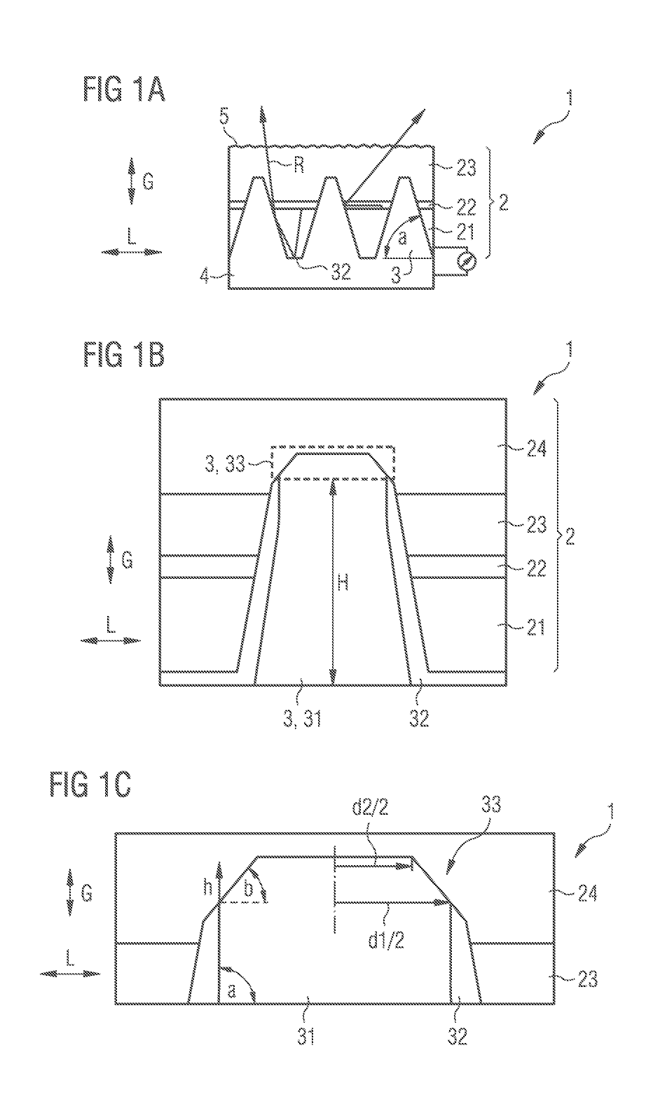

FIG. 1 schematic sectional views of an exemplary embodiment of an optoelectronic semiconductor chip described here,

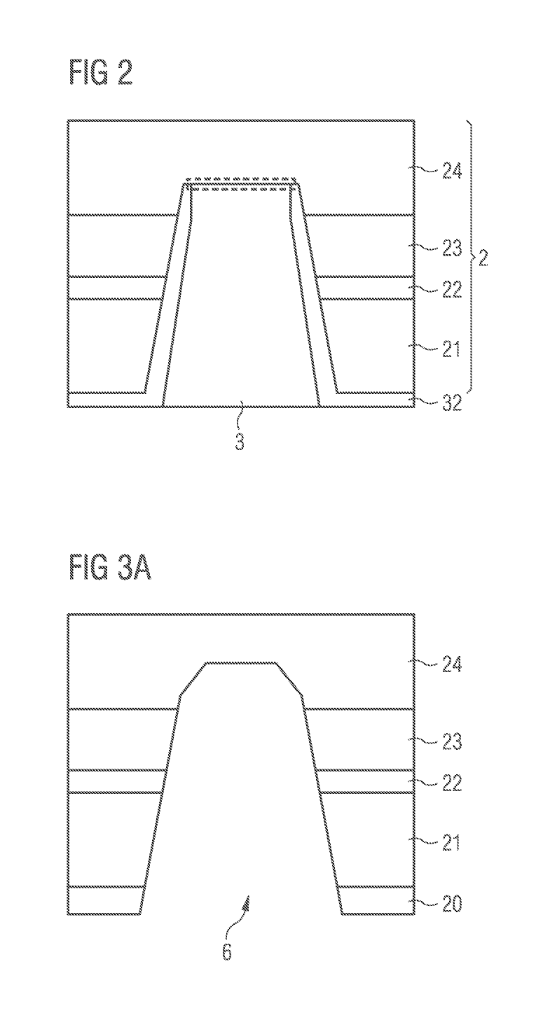

FIG. 2 a schematic sectional view of a variation of a semiconductor chip, and

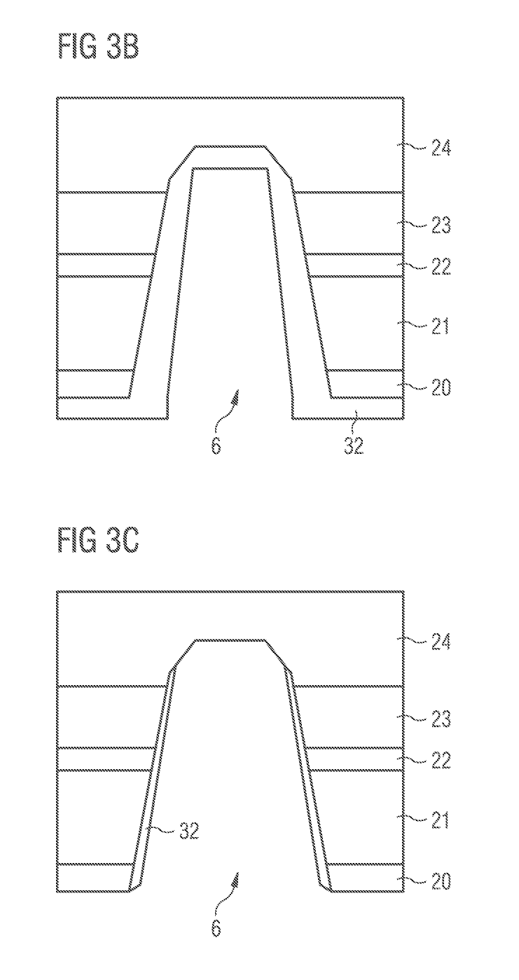

FIG. 3 schematic sectional views of method steps for the manufacture of an optoelectronic semiconductor chip described here.

In FIG. 1 an exemplary embodiment of an optoelectronic semiconductor chip 1 is shown. FIGS. 1B and 1C represent enlarged sections from FIG. 1A.

The semiconductor chip 1 comprises a semiconductor layer sequence 2. The semiconductor layer sequence 2 contains a first side 21 and a second side 23. For example, the first side 21 is n-type and the second side 23 is p-type. Located between the two sides 21, 23 is an active zone 22 for generating radiation. The semiconductor layer sequence 2 is based on the material system AlInGaP, for example.

Starting out from a carrier 4, several vias 3 extend through the first side 21 and through the active zone 22 into the second side 23. The second side 23 is thus electrically contacted through the electric vias 3. Located between the vias 3 and the semiconductor layer sequence 2 in a lateral direction L, perpendicular to a growth direction G of the semiconductor layer sequence 2, is an electric insulation layer 32. Reflection of the radiation R takes place on lateral surfaces of the vias 3 and on a boundary surface to the carrier 4 towards light outcoupling structures 5 on a side of the semiconductor layer sequence 2 remote from the carrier 4.

The first side 21 can be directly contacted electrically.

Alternatively it is possible that a current spreading layer, which is not shown, for example in the form of a metallic mirror, is located between the carrier 4 and the first side 21.

The vias 3, see FIGS. 1B and 1C, each have a base region 31 and a contact region 33. The base region 31 is surrounded all around by the insulation layer 32 along the lateral direction L. No direct current flow thus takes place from the base region 31 into the semiconductor layer sequence 2. The contact region 33 directly follows the base region 31 in the growth direction G and is constructed in one piece with this. In the contact region 33 the via 3 is in direct contact with the semiconductor layer sequence 2.

Both the contact region 33, identified in FIG. 1B by a rectangle drawn in with a dotted line, and the base region 31 are in the shape of a truncated cone. Related to the lateral direction L a shell surface of the base region 31 has a flank angle a and the contact region 33 has a flank angle b. The first flank angle a of the base region 31 is larger here than the second flank angle b of the contact region. A top side of the contact region 33 remote from the base region 31 can be formed flat or approximately flat. Deviating from the representation in FIG. 1, it is alternatively also possible that the first flank angle a of the base region 31 is smaller than or equal to the second flank angle b of the contact region.

The contact region 33 is formed due to the fact that the insulation layer 32 is in part not applied to the lateral surfaces of the via 3. A contact surface between the semiconductor layer sequence 2 and the via 3 is enlarged by this, so that a series resistance can be reduced. In addition, a scattering or deflection of radiation R, which is guided in the active zone 22, takes place through the vias 3. An increased light outcoupling efficiency can be achieved by this.

The height H of the base region 31 is, for example, 4 μm. A height h of the contact region 33 is, for example, 0.5 μm. A first diameter d1, at which the contact region 33 and the base region 31 abut one another, is 4 μm, for example. The first flank angle a is 65°, for example, and the second flank angle b is 55°, for example. Said values apply, for example, with a tolerance of at most 50% or 25% or 10%.

A second diameter d2 on the top side of the contact region 33 results trigonometrically from the height h of the contact region 33 and the first diameter d1. The second flank angle b is preferably chosen to be as large as possible, like the height h of the contact region 33. The base region 31 preferably consists predominantly of silver and/or gold. Located in the contact region 33 towards the second side 23, 24 is preferably a thin metal contact layer, for instance of platinum, which is not drawn in. Thin means, for example, a thickness of at most 500 nm or 100 nm or 30 nm.

FIG. 2 shows a variation of a semiconductor chip. According to FIG. 2, see the dashed rectangle, the via 3 has a flat top side without the graduated contact region from FIG. 1. An electric contact surface between the via 3 and the semiconductor layer sequence 2 is reduced by this.

Optionally, as in all other exemplary embodiments, the second side can be composed of two layers 23, 24. The layer 23 is a doping layer, for instance, with a comparatively low doping, in order to achieve a high crystal quality. The contact layer 24 is preferably highly doped to guarantee efficient lateral current spreading. Unlike what is shown in FIG. 1, the first side 21 can also be composed of several sublayers.

FIG. 3 illustrates schematically a manufacturing method for the vias 3. According to FIG. 3A, a hole 6 is etched in the semiconductor layer sequence 2. The graduated hole 6 is achieved, for example, by varying a chemical etching share and/or by layers in the semiconductor layer sequence 2 with different etching isotropies. The etching can be isotropic or anisotropic wet etching or directed dry etching.

In FIG. 3B it is shown that a material is subsequently applied for the insulation layer 32. This material is applied, for example, to all exposed surfaces with a comparatively great thickness.

Following this, see FIG. 3C, the material for the insulation layer 32 is then removed again in places by directed dry etching. Here this material is removed completely on horizontal surfaces in FIG. 3 and in the region of the future contact region, while on the steeper shell surfaces of the future base region a residual passivation for the insulation layer 32 remains. Then the hole 6 is filled with one or more metals, not shown.

According to FIG. 3, the first side 21 of the semiconductor layer sequence is also composed of two layers 21, 20. The layer 20 can be a current spreading layer.

The invention described here is not restricted by the description with reference to the exemplary embodiments. On the contrary, the invention comprises every new feature as well as every combination of features, which includes in particular every combination of features in the claims, even if this feature or this combination is not itself explicitly specified in the claims or exemplary embodiments.

This application claims the priority of the German application 10 2015 111 046.6, the disclosure content of which is hereby incorporated by back reference.

### REFERENCE SIGN LIST

1 Optoelectronic semiconductor chip
2 Semiconductor layer sequence
20 n-contact layer of the semiconductor layer sequence
21 n-type side of the semiconductor layer sequence
22 Active zone of the semiconductor layer sequence
23 p-type side of the semiconductor layer sequence
24 p-contact layer of the semiconductor layer sequence
3 Via
31 Base region
32 Electric insulation layer
33 Contact region
4 Carrier
5 Light outcoupling structure
6 Hole
a First flank angle (base region)
b Second flank angle (contact region)
d1 Maximum diameter of the contact region
d2 Minimum diameter of the contact region
G Growth direction
h Height of the contact region
H Base height
L Lateral direction
R Radiation

1-13. (canceled)

14. An optoelectronic semiconductor chip comprising:
a semiconductor layer sequence with a first side, a second side and an active zone lying between the first side and the second side, wherein the two sides are of different conductivity types; and
at least one via electrically contacting the first side with the second side through the active zone,
wherein the via has a base region comprising a cylinder, a truncated cone or a truncated pyramid, wherein the base region is surrounded in a lateral direction, perpendicular to a growth direction of the semiconductor layer sequence, by an electric insulation layer,
wherein the via has a contact region comprising a truncated cone, a truncated pyramid, or a spherical or aspherical body, the contract region directly following the base region in a direction parallel to the growth direction, wherein the contact region is in direct contact with the second side,
wherein a first flank angle of the base region is different from a second flank angle of the contact region, and wherein the first and second flank angles are related to the lateral direction.

15. The optoelectronic semiconductor chip according to claim 14,
wherein the first flank angle is larger by at least 3° and by at most 25° than the second flank angle, and
wherein the contact region comprises a truncated cone or a truncated pyramid.

16. The optoelectronic semiconductor chip according to claim 14, wherein the first flank angle is between 40° and 70° inclusive and the second flank angle is between 25° and 55° inclusive.

17. The optoelectronic semiconductor chip according to claim 14, wherein a height of the contact region, in the direction parallel to the growth direction, is between 0.05 μm and 4 μm inclusive.

18. The optoelectronic semiconductor chip according to claim 17,
wherein a base height H of the base region, in the direction parallel to the growth direction, is between 200 nm and 30 μm inclusive, and
wherein the following applies to the base height H and a height h of the contact region: 0.2≤H/h≤40.

19. The optoelectronic semiconductor chip according to claim 14, wherein the following applies to a height h of the contact region and to a mean diameter di of the via at a boundary between the contact region and the base region: 1≤d₁/h≤30.

20. The optoelectronic semiconductor chip according to claim 19, wherein the mean diameter is between 1 μm and 50 μm inclusive.

21. The optoelectronic semiconductor chip according to claim 14,
wherein the contact region at a boundary surface with the semiconductor layer sequence comprises one or more of the following materials: Au, Ag, ITO, ZnO, Ni, Ge, Zn, Rh, Pd, Pt, Ti, and
wherein the base region essentially consists of one or more of the following materials:
Ag, Au, ITO, ZnO, Ni, Ge, Zn, Rh, Pd, Pt, Ti, Sn, W.

22. The optoelectronic semiconductor chip according to claim 14,
wherein the active zone is configured to emit radiation with a dominant wavelength X and the following applies in respect with a mean thickness D of the insulation layer: D>λ/4n, and
wherein n is a refractive index of the insulation layer at the dominant wavelength.

23. The optoelectronic semiconductor chip according to claim 14, wherein the insulation layer tapers in the direction of the contact region.

24. The optoelectronic semiconductor chip according to claim 14, wherein the optoelectronic semiconductor chip comprises a plurality of vias with at least 20 and at most 500 vias per mm².

25. The Optoelectronic semiconductor chip according to claim 14, wherein the semiconductor layer sequence comprises AlInGaP or AlInGaAsP.

26. The optoelectronic semiconductor chip according to claim 14,
wherein the second side is p-doped, has a doping layer and a more highly doped contact layer,
wherein the doping layer lies between the contact layer and the active zone, and
wherein the at least one via extends into the contact layer.

27. An optoelectronic semiconductor chip comprising:
a semiconductor layer sequence comprising a first side, a second side and an active zone lying between the first side and the second side, wherein the two sides are of different conductivity types; and
at least one via electrically contacting the first side with the second side through the active zone,
wherein the via has a base region comprising a cylinder, a truncated cone or a truncated pyramid, wherein the base region is surrounded in a lateral direction, perpendicular to a growth direction of the semiconductor layer sequence, by an electric insulation layer,
wherein the via has a contact region comprising a truncated cone, a truncated pyramid or a spherical or aspherical body, wherein the contact region directly follows the base region in a direction parallel to the growth direction, and wherein the contact region is in direct contact with the second side,
wherein a first flank angle of the base region is larger than a second flank angle of the contact region by at least 3° and by at most 25°, wherein the first and the second angles are related to the lateral direction so that the first flank angle is between 40° and 70° inclusively and the second flank angle is between 25° and 55° inclusively, and
wherein the following applies to a height h of the contact region and to a mean diameter d₁ of the via at a boundary between the contact region and the base region: 7≤d₁/h≤20.
